(19) United States
(12) Patent Application Publication
(10) Pub. No.: US 2009/0151779 A1
(43) Pub. Date: Jun. 18, 2009

(54) Redox Couples, Compositions and Uses Thereof

(76) Inventors: Amer Hammami, Quebec (CA); Benoit Marsan, Quebec (CA); Michel Armand, Saint-Martin d'Uriage (FR); Gregory Hersant, Montréal (CA)

Correspondence Address: JORDAN AND HAMBURG LLP, 122 EAST 42ND STREET, SUITE 4000, NEW YORK, NY, 10168, US

(21) Appl. No.: 12/225,525

(22) PCT Filed: Mar. 29, 2007
(86) PCT No.: PCT/CA2007/000519

§ 371 Date: Nov. 14, 2008

(30) Foreign Application Priority Data
Mar. 29, 2006 (CA) 2541232

(51) Int. Cl. H01L 31/00; C09K 3/00

(52) U.S. Cl. 136/252; 252/188.2

(57) ABSTRACT

There is provided a composition comprising a first compound chosen from compounds of formulas (I) and (III) and a second compound chosen from compounds of formulas (II) and (IV):

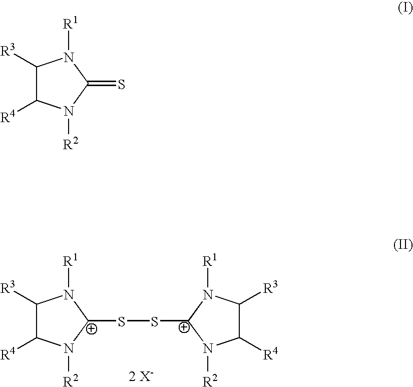

A-S⁻M⁺ (III)

A-S—S-A (IV)

Various chemical entities can be used for R¹ to R⁴, A, M, and Z. This composition can be particularly useful as a redox couple.

### TECHNICAL FIELD

The present document relates to improvements in the field of electrochemistry. In particular, this document relates to compositions that can be used as redox couples.

### BACKGROUND OF THE INVENTION

Sun is a free and unlimited renewable source of energy. It can be converted directly to electricity by using p-n heterojunction solar cells (like silicon-based devices), electrochemical photovoltaic cells (EPC's) or dye-sensitized solar cells (DSSC's). EPC's are systems based on a junction between a semiconductor (p-type or n-type) and an electrolyte containing one redox couple; an auxiliary electrode completes the device. Owing to the built-in potential developed at the semiconductor/electrolyte interface, the photogenerated electrons and holes are separated and used to undergo oxidation and reduction reactions at the electrodes, respectively with the reduced and oxidized species of the redox couple. On the other hand, DSSC's are systems based on a junction between dye-chemisorbed nanocrystalline TiO₂ particles, deposited on a conductive glass substrate, and a non-aqueous electrolyte containing the I⁻/I₃⁻ redox couple; a platinum-coated conductive glass electrode completes the device. In such systems, the light absorption (by the dye molecules) and charge-carrier transport (in the conduction band of the semiconductor to the charge collector) processes are separated. Homogeneous oxidation of I⁻ species serves to regenerate the photoexcited dye molecules whereas the heterogeneous reduction of I₃⁻ species takes place at the platinum-coated electrode.

There is extensive prior art on EPC's and DSSC's. However, one main issue still to resolve is to find a redox couple that is electrochemically stable, non-corrosive, with a high degree of reversibility and a high electropositive (in conjunction with n-type semiconductors) or electronegative (in conjunction with ptype semiconductors) potential, and colorless (substantially optically clear) when used in concentrations allowing high electrolyte ionic conductivities.

I⁻/I₃⁻ is the most investigated redox couple for DSSC's. Cations may be alkali metals or organic cations containing quaternary ammonium groups such as dialkylimidazolium (Papageorgiou et al., J. Electrochem. Soc. 143. 3099 (1996) Stathatos et al., Chem. Mater., 15, 1825 (2003)). The main limitations of this system are (i) the fact that it absorbs a significant part of the visible light of the solar spectrum when used in the concentration range giving reasonably good ionic conductivities (which leads to a decrease in the energy conversion efficiency); (ii) its low redox potential (which limits the device photovoltage); (iii) its reactivity towards metals such as silver copper, etc. (which causes a difficulty about the use of these metals as a current collector); and (iv) the high volatility of the electrolyte when usual organic solvents are employed (which causes an irreversible instability of the device).

Nusbaumer et al. in Chem. Eur. J., 9, 3756 (2003) studied alternative redox couples for DSSC's based on much more expensive cobalt complexes. Although the fact that these systems are less colored and possess more positive potential than the I⁻/I₃⁻ redox couple, the oxidized species (Co^{III}) may be reduced at the conductive glass acting as a substrate for the TiO₂ particles, in which case the energy conversion efficiency is decreased. Moreover, regeneration of the dye molecules by the reduced species (Co^{II}) (absolutely necessary to the operation of the device) may become more difficult due to association of the oxidized species (Co^{III}) with the sensitizer. Another serious disadvantage of this Co^{III}/Co^{II} system is the bigger molecular size that causes a limitation of photocurrent under high illumination intensity (100 mW/cm²).

In EPC's, various redox couples dissolved in water were studied, such as Fe(CN)₆⁴⁻/Fe(CN)₆³⁻, I⁻/I₃⁻, Fe²⁺/Fe³⁺, S²⁻/Sₙ²⁻, Se²⁻/Seₙ²⁻ and V²⁺/V³⁺, and devices exhibiting a good energy conversion efficiency were generally unstable under sustained white light illumination due to photocorrosion of the semiconductor electrode. The use of non-aqueous electrolytic media (liquid, gel or polymer) could eliminate the photocorrosion process, but in these cases the number of redox couples is very limited. For examples, the I⁻/I₃⁻ (Skotheim and Inganäs, J. Electrochem. Soc., 132, 2116 (1985)) and S²⁻/Sₙ²⁻ (Vijh and Marsan, Bull. Electrochem., 5, 456 (1989)) redox couples were dissolved in polyethylene oxide (PEO) and modified PEO, respectively, and investigated in EPC's. In addition to the coloration and potential problems occurring with the I⁻/I₃⁻ couple, as mentioned above, the device stability has not been demonstrated. Regarding the S²⁻/Sₙ²⁻ redox couple, the same problems were observed but in this case the stability under white light illumination has been reported.

A cesium thiolate (CsT)/disulfide (T₂) redox couple, where T⁻ stands for 5-mercapto-1-methyltetrazolate ion and T₂ for the corresponding disulfide, was dissolved in modified PEO and studied in an EPC (Philias and Marsan, Electrochim. Acta, 44, 2915 (1999)). Its more positive potential than that of the S²⁻/Sₙ²⁻ redox couple, its better dissociation in organic media including polymers (giving much more conductive electrolytes) and its much less intense coloration are responsible for the significant increase of the device energy conversion efficiency. Despite this improvement, the T⁻/T₂ redox couple is quite electrochemically irreversible, with a difference between the anodic (Eₚₐ) and cathodic (E_{pc}) peak potentials, symbolized as ΔEₚ, of 1.70 V at a platinum electrode (scanning speed of 100 mV/s), even when put in a more conductive gel electrolyte comprising 50 mM of T⁻ and 5 mM of T₂ dissolved in 80% DMF/DMSO (60/40) and incorporated in 20% poly(vinylidene fluoride), PVdF. Furthermore, its solubility is not very good in organic media.

Thus, based on prior art relative to redox couples for EPC's and DSSC'S, there are no redox couples permitting to maximize the device energy conversion efficiency.

Therefore, new redox couples having improved properties with respect to the redox couples of the prior art would be highly desired. Moreover, redox couples permitting to avoid the drawbacks of the prior art are also highly desired.

### SUMMARY OF THE INVENTION

It is therefore an object to provide a redox couple which would overcome the above-mentioned drawbacks.

It is another object to provide a redox couple which has a good solubility.

It is another object to provide a redox couple which is substantially colorless or substantially optically clear at concentrations permitting a good conductivity.

It is another object to provide a redox couple which has a low vapor pressure.

It is another object to provide a redox couple which has a high thermal stability.

It is another object to provide a redox couple which is highly electropositive as example for application in DSSC'S or EPC's using n-type semiconductors.

It is another object to provide a redox couple which is highly electronegative as example for application in EPC's using p-type semiconductors.

It is another object to provide a redox couple which will not corrode other components when used in a device.

It is another object to provide a redox couple which has a small ΔEₚ.

It is another object to provide a redox couple which has a high degree of reversibility.

In accordance with one aspect, there is provided a composition comprising a first compound chosen from compounds of formulas (I) and (III) and a second compound chosen from compounds of formulas (II) and (IV):

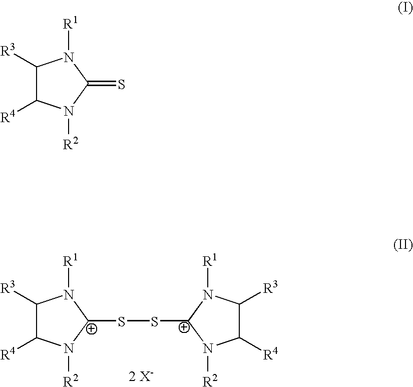

A-S⁻M⁺ (III)

A-S—S-A (IV)
wherein
   R¹ and R² are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, or R¹ and/or R² is part of a polymer chain or network
   R³ and R⁴ are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, F, Cl, Br, I, CF₃, CN, SO₃H, CₙF₂ₙ₊₁, HCₙF₂ₙ₊₁—, CF₃O—, CₙF₂ₙ₊₁O—, HCₙF₂ₙ₊₁O—, CF₃S—, CₙF₂ₙ₊₁S—, HCₙF₂ₙ₊₁S—, ClCₙF₂ₙ₊₁—, ClCₙF₂ₙ₊₁O—, ClCₙF₂ₙ₊₁S—, BrCₙF₂ₙ₊₁—, BrCₙF₂ₙ₊₁O—, BrCₙF₂ₙ₊₁S—, ICₙF₂ₙ₊₁—, ICₙF₂ₙ₊₁O—, ICₙF₂ₙ₊₁S, CH₂═CHCₙF₂ₙ₊₁—, CH₂═CHCₙF₂ₙ₊₁O—, CH₂═CHCₙF₂ₙ₊₁S—, R²OCₙF₂ₙ₊₁—, R²OCₙF₂ₙ₊₁O—, R²OCₙF₂ₙ₊₁S—, CF₃CH₂—, CF₃CH₂O—, (CF₃)₂CH—, (CF₃)₂CHO—, CHF₂—, CHF₂O—, CHF₂S—, CClF₂—, CClF₂O—, CClF₂S—, CCl₂F—, CCl₂FO—, CClF₂S—, CCl₃—, CCl₃—, C₆F₅—, CF₃C₆F₄—, C₆F₅S—, CF₃C₆F₄O—, 3,5-(CF₃)₂C₆H₂—, C₆Cl₅—, C₆Cl₅O—, FSO₂CF₂—, ClSO₂(CF₂)ₙ—SO₃(CF₂)ᵣ—, CO₂(CF₂)ᵣ—, FSO₂N⁽⁻⁾SO₂(CF₂)ᵣ—, CF₃SO₂N⁽⁻⁾SO₂(CF₂)ₙ—, CₙF₂ₙ₊₁SO₂N⁽⁻⁾SO₂(CF₂)ᵣ—R²SO₂N⁽⁻⁾SO₂(CF₂)ₙ—, FSO₂(CF₂)ₙ—, ClSO₂(CF₂)ₙ—, CₙF₂ₙ₊₁SO₂N⁽⁻⁾(CF₂)ₙ—, and R²SO₂N⁽⁻⁾(CF₂)ₙ— or
   R³ and/or R⁴ is part of a polymer chain or network, or absent
   X⁻ is (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻NO₃⁻, 2.3HF, Cl⁻, Br⁻, I⁻, PF₆⁻, BF₄⁻, ClO₄ SCN⁻;
   M is H, an organic cation or an inorganic cation;
   A is a C₁-C₁₂ heteroaryl, a C₁-C₁₂ heterocyclyl, C₆-C₁₂ aryl, C₆-C₃₀ aralkyl, or C₆-C₃₀ alkylaryl
wherein the alkyl, cycloalkyl, heterocyclyl, alkenyl, alkynyl, aryl, aralkyl, alkylaryl, heteroaryl, alkylheteroaryl, and alkylheterocyclyl optionally includes a heteroatom in the form of —O—, ═N—, —S—, ═P—, ═(P═O)—, —SO—, —SO₂—;
wherein the alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from R³, R⁴, F, Cl, Br, I, OH, a C₁-C₆ alkoxy, a C₁-C₆ hydroxy alkyl, NO₂, CN, CF₃, SO₃H, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂ₙ—, CH₂═CHCₚH₂ₚ—, CH₂═CHC₆H₅—. CH₂═CHC₆H₄CₚH₂ₚ₊₁—, and CH₂═CHCₚH₂ₚC₆H₄—;
   n is an integer having a value from 1 to 48;
   m is an integer having a value from 2 to 12; and
   p is an integer having a value from 1 to 48.

It was found that such compositions are quite useful as redox couples.

In accordance with another aspect, there is provided a redox couple according to scheme 1 or scheme 2:

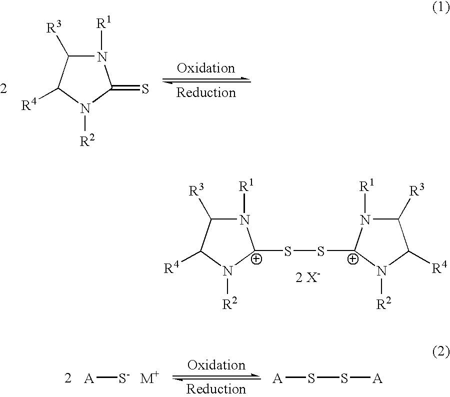

wherein R¹, R², R³, R⁴, X⁻, M and A are as previously defined.

It was found that the redox couples previously presented can have a very good degree of reversibility since they can have a relatively small ΔEₚ. Moreover, it has been found that these redox couples have a high thermal stability, and a good solubility in various solvents. It also has been found that these redox couples are substantially colorless (or substantially optically clear) at concentrations permitting a good conductivity. Such characteristics make them particularly interesting in various applications like solar cells or photovoltaic cells. It also has been found that these redox couples do not have tendency to corrode other components when used in devices such as solar cells or photovoltaic cells.

The expression “redox couple” as used herein refers to a couple comprising an oxidized member and a reduced member.

The term “aryl” as used herein refers to a cyclic or polycyclic aromatic ring. According to one example, the aryl group can be phenyl or naphthyl.

The term “heteroaryl” as used herein refers to an aromatic cyclic or fused polycyclic ring system having at least one heteroatom chosen from N, O, and S. Examples include heteroaryl groups such as furyl, thienyl, pyridyl, quinolinyl, isoquinolinyl, indolyl, isoindolyl, triazolyl, pyrrolyl, tetrazolyl, imidazolyl, pyrazolyl, oxazolyl, thiazolyl, benzofuranyl, benzothiophenyl, carbazolyl, benzoxazolyl, pyrimidinyl, benzimidazolyl, quinoxalinyl, benzothiazolyl, naphthyridinyl, isoxazolyl, isothiazolyl, purinyl, quinazolinyl, and so on.

The term “heterocyclyl” includes non-aromatic rings or ring systems that contain at least one ring having at least one hetero atom (such as nitrogen, oxygen or sulfur). For example, such a term can include all of the fully saturated and partially unsaturated derivatives of the above mentioned heteroaryl groups. Examples of heterocyclic groups include pyrrolidinyl, tetrahydrofuranyl, morpholinyl, thiomorpholinyl, piperidinyl, piperazinyl, thiazolidinyl, isothiazolidinyl, and imidazolidinyl.

In the compositions and redox couples previously presented, A can be of formula

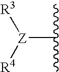

wherein Z is chosen from

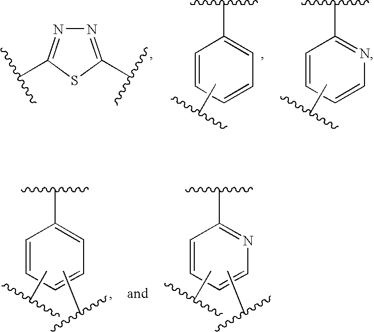

wherein R₃ and R₄ are as previously defined.

A can also be chosen from thiadiazoles, pyridines, and phenylenes. The thiadiazoles, pyridines, and phenylenes can be unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂ₙ—, CH₂═CHCₚH₂ₚ—, CH₂═CHC₆H₅—, CH₂═CHC₆H₄CₚH₂p+₁—, and CH₂═CHCₚH₂ₚC₆H₄—.

A can also be chosen from

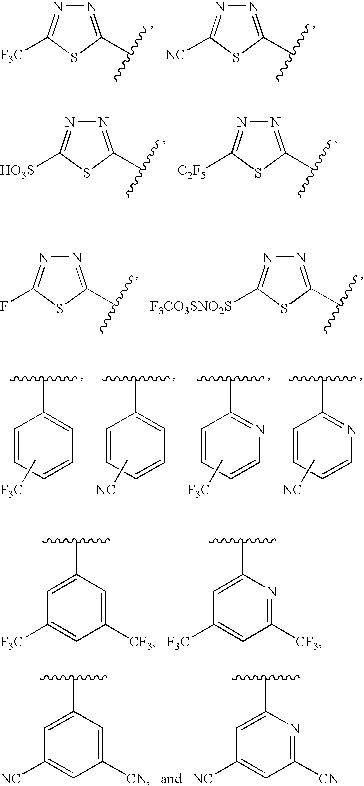

In the compositions and redox couples, X⁻ can be (CF₃SO₂)₂N⁻, (C₂F₅SO₂)₂N⁻, (CF₃SO₂)₃C⁻, CF₃SO₃⁻, (CN)₂N⁻, PF₆⁻, BF₄⁻ or ClO₄⁻. For example, X⁻ is (CF₃SO₂)₂N⁻.

M can be chosen from a positively charged C₁-C₁₂ heteroaryl or a C₁-C₁₂ heterocyclyl, wherein said heteroaryl or said heterocyclyl is unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂ₙ—, CH₂═CHCₚH₂ₚ—, CH₂═CHC₆H—, CH₂═CHC₆H₄C₉H₂ₚ₊₁—, and CH₂═CHCₚH₂ₚC₆H₄—.

M can also be an inorganic cation such as Li⁺, K⁺, Na⁺, and Cs⁺. M can also be an organic cation of formula

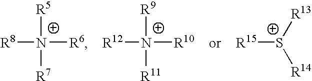

wherein
   R⁵, R⁶, R⁷ and R⁸ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl;
   R⁹, R¹⁰, R¹¹ and R¹² are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl; and
   R¹³, R¹⁴ and R¹⁵ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl,
wherein the alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁₃ C₁-C₁₂ alkyl which is linear or branched, C₆-C₁₂ aryl, CₙH₂ₙ₊₁, C₆H₅CₚH₂ₚ—, CₚH₂ₚ₊₁C₆H₄—, CₚH₂ₚ₊₁C₆H₄CₙH₂ₙ—, CH₂═CHCₚH₂ₚ—, CH₂═CHC₆H₅—, CH₂═CHC₆H₄CₚH₂ₚ₊₁—, and CH₂═CHCₚH₂ₚC₆H₄—.

M can also be chosen from N-substituted imidazoliums. The substituents can each independently be a C₁-C₁₂ alkyl or a C₁-C₆ alkyl which is linear (for example 1,3-methylethylimidazolium) or branched or tetralkylammoniums, wherein each of the alkyl groups is independently C₁-C₁₂ alkyl which is linear or branched (for example tetrabutylammonium).

The compositions can further comprise a solvent chosen from nitriles (such as CH₃CN), CH₂Cl₂, alcohols (such as ethanol, isopropanol), DMSO, amides (such as DMF), hexane, heptane, toluene, linear carbonates (such as dimethylcarbonate, diethylcarbonate, ethylmethylcarbonate), cyclic esters (such as ethylene carbonate, propylene carbonate), urea (tetramethylurea), ionic liquids such as dialkylimidazolium, trialkylsulfonium, and quaternary amine (such as C₁-C₂₀ tetraalkylammonium) and quaternary phosphonium (such as C₁-C₂₀ tetraalkylphosphonium or C₆-C₁₂ tetraarylphosphonium) salts associated with stable anion such as (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻, NO₃⁻, 2.3HF, Cl⁻, Br⁻, I⁻, PF₆⁻, BF₄⁻, ClO₄⁻, SCN⁻, and mixtures thereof. For example, the solvent is nitriles (such as CH₃CN), amides (such as DMF), linear carbonates (such as dimethylcarbonate, diethylcarbonate, ethylmethylcarbonate), cyclic esters (such as ethylene carbonate, propylene carbonate), ionic liquids such as dialkylimidazolium, trialkylsulfonium, and quaternary amine (such as C₁-C₂₀ tetraalkylammonium) and quaternary phosphonium (such as C₁-C₂₀ tetraalkylphosphonium or C₆-C₁₂ tetraarylphosphonium) salts associated with stable anion such as (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻, NO₃⁻, 2.3HF, Cl⁻, Br⁻, I⁻, PF₆⁻, BF₄⁻, ClO₄⁻, SCN⁻ and mixtures thereof.

In the compositions, the first compound can be, for example, present in the composition in a molar ratio of about 0.1 to about 99.9% and the second compound can be present in a molar ratio of about 99.9 to about 0.1%. According to another example, the first compound can be present in the composition in a molar ratio of about 5.0 to about 95.0% and the second compound is present in a molar ratio of about 95.0 to about 5.0%.

The compositions can be in the form of an uncolored and/or translucid solution. The compositions can also be substantially optically clear.

The compositions can comprise a compound of formula (I) and a compound of formula (II) or they can comprise a compound of formula (III) and a compound of formula (IV).

In accordance with another aspect, there is provided a photovoltaic cell comprising an anode, a cathode, and a composition as previously defined in the present document.

In accordance with another aspect, there is provided a photovoltaic cell comprising an anode, a cathode, a composition as defined in the present document, and a solvent, a polymer, a molten salt, an ionic liquid, a gel or any combination thereof.

In accordance with another aspect, there is provided a photovoltaic cell comprising an anode, a cathode, and a redox couple as defined in the present document.

In accordance with another aspect, there is provided a photovoltaic cell comprising an anode, a cathode, a redox couple as defined in the present document, and a solvent, a polymer, a molten salt, an ionic liquid, a gel or any combination thereof.

The redox couples of the present document can be used in a solar cell, a fuel cell, a battery, a sensor or a display.

### BRIEF DESCRIPTION OF FIGURES

Further features and advantages will become more readily apparent from the following description of specific embodiments as illustrated by way of examples in the appended figures wherein:

FIG. 1 shows a cyclic voltammogram of a composition according to one embodiment, wherein the oxidized member (compound 5) and the reduced member (compound 3) of the composition are present at the beginning of the experiment in a 1:1 ratio.

FIG. 2 shows another cyclic voltammogram of the composition tested in the voltammogram of FIG. 1, wherein the ratio reduced member (compound 3)/oxidized member (compound 5) is about 2:1 at the beginning of the experiment;

FIG. 3 shows another cyclic voltammogram of the composition tested in the voltammogram of FIG. 1, wherein the ratio reduced member (compound 3)/oxidized member (compound 5) is about 1:2 at the beginning of the experiment;

FIG. 4 shows cyclic voltammograms comparing the composition at various proportions of the reduced and oxidized members, which are the proportions analyzed in FIGS. 1 to 3;

FIG. 5 shows other cyclic voltammograms comparing two different working electrodes with the composition used in the same proportion as in the voltammogram of FIG. 3;

FIG. 6 shows a cyclic voltammogram of a composition according to another embodiment, wherein the ratio reduced member (compound 7)/oxidized member (compound 8) is about 3:1 at the beginning of the experiment;

FIG. 7 shows a cyclic voltammogram of a composition according to another embodiment, wherein the ratio reduced member (compound 9)/oxidized member (compound 10) is about 3:1 at the beginning of the experiment;

FIG. 8 shows a cyclic voltammogram of a composition according to another embodiment, wherein the ratio reduced member (compound 11)/oxidized member (compound 12) is about 2:1 at the beginning of the experiment;

FIG. 9 shows a cyclic voltammogram of a composition according to another embodiment, wherein the ratio reduced member (compound 13)/oxidized member (compound 14) is about 1:3 at the beginning of the experiment;

FIG. 10 shows a cyclic voltammogram of a composition according to another embodiment, wherein the ratio reduced member (compound 17)/oxidized member (compound 18) is about 5:1 at the beginning of the experiment;

FIG. 11 is a comparison between the visible spectrum of a solution comprising compounds 17 and 18 in ethyl-1-methyl-3-imidazolium-bis-fluoro-sulfonylimide (EMITFSI) and the visible spectrum of EMI⁺I⁻/I₂ in EMITFSI; and

FIG. 12 shows cyclic voltammograms of the solution comprising compounds 17 and 18 in EMITFSI, wherein stability tests at a temperature of 70° C. have been carried out.

### DETAILED DESCRIPTION OF VARIOUS EMBODIMENTS

The following examples are given in a non-limitative manner.

For example, the compositions and redox couples of the present document can be made by the following general procedure.

### Synthesis of Compound 3 (1,3-diethyl-imidazolidine-2-thione)

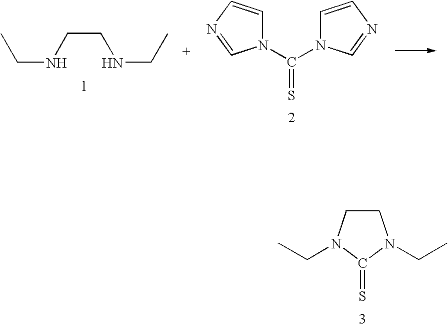

In a 100 mL two-neck flask 30 mL of tetrahydrofuran (THF), 1.6 mL (11.2 mmol; 1 eq) of 1 were introduced. Then, 2 g (11.1 mmol; 1 eq) of 2 were added. The resulting solution was stirred for 12 hours. The reaction was performed in a glove box. The reaction mixture was then concentrated with a rotative evaporator and an orange paste is obtained. Thereafter, approximately 30 mL of Et₂O were added to it. 3 then precipitated and the impurities were solubilized in Et₂O. A filtration on paper was carried out and 3 was thus recovered. 3 was concentrated using a rotative evaporator. Again, an orange paste was obtained and approximately 30 mL of Et₂O were added to this mixture. 3 precipitated. This step was repeated until no more precipitate was obtained when Et₂O is added.

### Synthesis of Compound 5 (1,3-diethyl-imidazolidine-2-thione Disulfide)

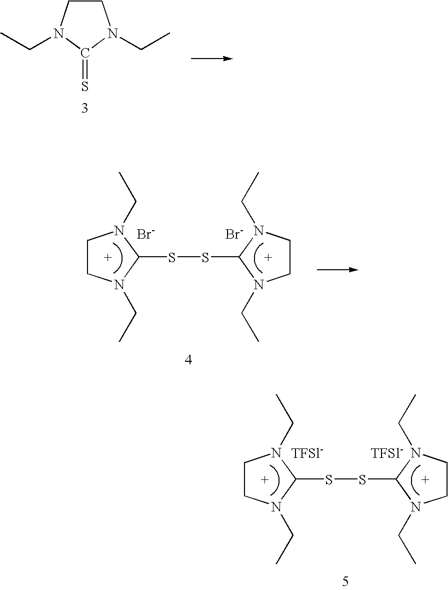

In a 125 mL rectional flask, 1 g (6.32 mmol; 1 eq) of compound 3 was introduced with 30 mL of water. 0.2 mL of Br₂ (0,50g: 3.16 mmol; ½ eq) were then added dropwise. It is also possible to add an excess of Br₂. The solution was stirred for 1 hour at room temperature. In a separate 50 mL two-neck flask filled with 20 mL of water, 1.81 g (6.32 mmol: 1 eq) of lithium bis(trifluoromethanesulfonyl)imide (LiTFSI) were dissolved. This mixture was then added to the previous one. A yellowish oil (5) was formed. Compound 5 was extracted with 50 mL of Et₂O. The organic layer was separated and dried with anhydrous MgSO₄. The organic layer was then concentrated using a rotative evaporator. A yellowish oil 5 was obtained.

### Synthesis of Compound 6 (Potassium Salt of 5-methyl-2-mercapto-1,3,4-thiadiazole)

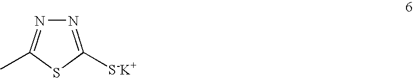

Commercially available 5-methyl-2-mercapto-1,3,4-thiadiazole from ALDRICH™ (1 eq) was neutralized with potassium carbonate K₂CO₃ (0.5 eq) in methanol (concentrations: 0.5 M). The resulting solution was stirred in an ultrasonic bath until complete dissolution of K₂CO₃ (almost 2 h 30 min). The mixture was then filtrated with a Büchner funnel fitted with a filter Whatman no. 40 (“Ashless”). The filtrate was concentrated with a rotative evaporator and a slightly yellow solid was obtained and dried under high vacuum in a desiccator for 12 h. At last, the slightly yellow solid 6 was rinsed with CH₂Cl₂ and dried under vacuum (yield≈70%). Compound 6 (C₃H₃KN₂S₂) has a molecular weight of 170.29 g/mol.

### Synthesis of Compound 7 (Tetrabutylammonium (TBA) Salt of the 5-methyl-2-mercapto-1,3,4-thiadiazole)

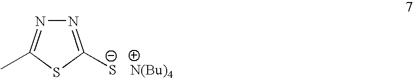

In a first reaction flask, acetone and compound 6 (1 eq) were introduced (concentration: 1 M). In a second reaction flask acetone and commercially available tetrabutylammonium perchlorate from ALFA AESAR™ were introduced (concentration: 1 M). After complete dissolution of the compounds in each flask, the solution of tetrabutylammonium perchlorate was added to the solution of 7. The resulting mixture was stirred in an ultrasonic bath for 1 hour and a white solid (KClO₄) starts to precipitate. Then, the mixture was introduced in a freezer for one night in order to complete the crystallisation of KClO₄. After filtration of the reaction medium with a Büchner funnel fitted with a filter paper Whatman no. 40 (Ashless), the filtrate was concentrated with a rotative evaporator and a slightly yellow solid 7 was obtained, then dried under high vacuum in a desiccator for 12 hours. The yield was quantitative. Compound 7, C₁₉H₃₉N₃S₂ has a molecular weight of 373.66 g/mol.

### Synthesis of Compound 8

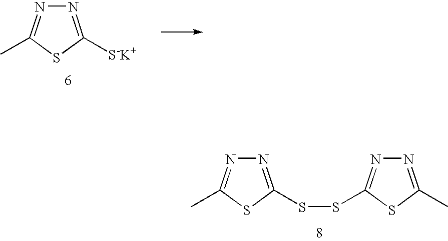

Compound 6 (200 mg; 0.89 mmol, 1 eq) was charged into 50 mL flask filled with 20 mL H₂O. After complete dissolution, I₂ (50.3 mg; 0.44 mmol; 0.5 eq) was added to the solution. Immediately a white suspension appeared. The solution was stirred until I₂ was completely dissolved, then the white solid was filtrated under vacuum with a Büchner funnel fitted with a Whatman filter (no. 40: Ashless). The solid was washed with H₂O (100 mL) and dried under vacuum for 24 h to give 97.34 mg (yield of 30%) of product 8.

### Synthesis of Compound 9 (Potassium Salt of 2-mercapto-1,3,4-thiadiazole)

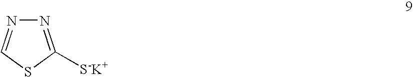

2-mercapto-1,3,4-thiadiazole (1.18 g, 10 mM, 1 eq) was neutralized with potassium carbonate K₂CO₃ (0.5 eq) in methanol (concentrations: 0.5 M). The resulting solution was stirred in an ultrasonic bath until complete dissolution of K₂CO₃ (almost 2 h 30 min). The mixture was then filtrated with a Büchner funnel fitted with a filter, Whatman no. 40 (“Ashless”). The filtrate was concentrated with a rotative evaporator and a slightly yellow solid was obtained and dried for 12 h at 60° C. At last, the slightly yellow solid 6 was washed with 50 mL CH₂Cl₂ and dried under vacuum over night at 60° C. (yield≈80%).

### Synthesis of Compound 10

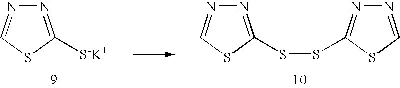

Compound 9 (500 mg; 0.32 mmol, 1 eq) was charged into 50 mL flask filled with 20 mL distilled H₂O. After complete dissolution, I₂ (56.3 mg; 0.44 mmol; 0.5 eq) was added to the solution. Immediately, a white suspension appeared. The solution was stirred until I₂ was completely dissolved, then the white precipitate was filtrated under vacuum with a Büchner funnel fitted with a Whatman filter (no. 40: Ashless). The solid was washed with H₂O (100 mL) and dried under vacuum for 24 h at 60° C. to give 29.9 mg (yield of 40%) of product 10.

### Synthesis of Compound 11 (4-Methyl-5-trifluoromethyl-4H-1,2,4-triazolin-3(2H)-thione Potassium Salt)

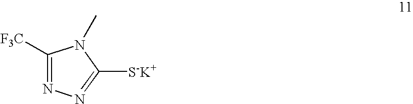

4-Methyl-5-trifluoromethyl-4H-1,2,4-triazolin-3(2H)-thione (1.82 g, 10 mM, 1 eq) was neutralized with potassium carbonate K₂CO₃ (0.5 eq) in methanol (concentration: 0.5 M). The resulting solution was stirred in an ultrasonic bath until complete dissolution of K₂CO₃ (almost 2 h 30 min). The mixture was then filtrated with a Büchner funnel fitted with a filter Whatman no. 40 (“Ashless”). The filtrate was concentrated with a rotative evaporator and a white solid was obtained and dried under vacuum for 12 h at 60° C. The white solid 11 was rinsed with 100 mL CH₂Cl₂ and dried under vacuum (yield≈75%). Compound 11 (C₄H₃F₃KN₃S) has a molecular weight of 220.96 g/mol.

### Synthesis of Compound 12

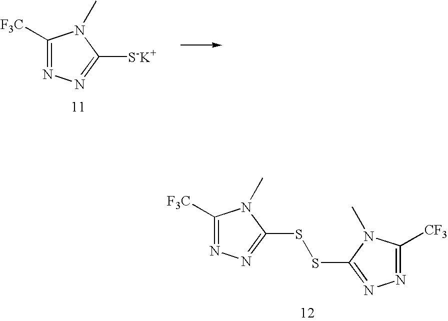

Compound 11 (500 mg; 0.23 mmol, 1 eq) was charged into 50 mL flask filled with 20 mL distilled H₂O. After complete dissolution, I₂(14.1 mg; 0.12 mmol; 0.5 eq) was added to the solution. Immediately, a white suspension appeared. The solution was stirred until I₂ was completely dissolved, then the white solid was filtrated out under vacuum with a Büchner funnel fitted with a Whatman filter (no. 40: Ashless). The solid was washed with H₂O (100 mL) and dried under vacuum for 24 h at 60° C. to give 25.1 mg (yield of 30%) of compound 12.

### Synthesis of Compound 14

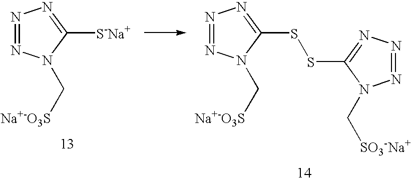

5-Mercapto-1H-tetrazole-1-methanesulfonic acid disodium salt 13 (500 mg 0.21 mM, 1 eq) was charged into 50 mL flask filled with 30 mL DMSO. The well-stirred mixture was heated at 65° C. for 2 hours and then concentrated. The white solid was washed with acetone (100 mL), purified by recrystallization in a mixture of methanol and ethanol, and then, dried under vacuum for 24 h at 60° C. to give 73.9 mg (yield of 80%) of compound 14.

### Synthesis of Compound 17

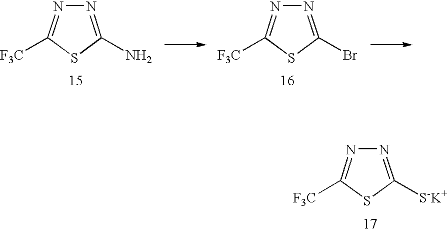

Compound 15 (10.0026 g; 59.1 mmol; 1 eq) was introduced in a 250 mL reaction flask. This flask was put in an ice bath and a solution of HBr (48% in H₂O; 46.0 mL) as well as water (12.0 mL) were added. After the complete dissolution (5 min) of compound 15, a solution of NaNO₂ (8.3214 g; 120.0 mmol; 2 eq) in H₂O (16 mL) was added dropwise over a period of 45 minutes (gas emission and brown coloration were observed). The resulting solution was stirred for 2 hours at room temperature. Then, the reaction mixture was extracted twice with 40 mL of Et₂O. The organic layers were separated, washed with a portion of 60 mL of water and dried over anhydrous MgSO₄. After concentration of the solution with a rotative evaporator, a brown oil (compound 16) was obtained.

Compound 16 was then added dropwise over a period of 40 minutes to a 150 mL reaction flask containing Li₂S (8.1432 g; 177.3 mmol). The reaction mixture was stirred for 2 h and then concentrated. The residue was cooled to −20° C. and a solution of HCl (3 M; 50 mL) was added dropwise over a period of 20 minutes in order to destroy the excess of Li₂S. The crude product was then extracted twice with 40 mL of Et₂O. The organic layers were washed with portions of 80 mL of saturated solutions of Na₂S₂O₃ and NaCl, H₂O and dried over anhydrous MgSO₄. After concentration with a rotative evaporator, a solid was obtained. The sublimation of this solid under vacuum (heat temperature of 70° C.) allowed to provide translucent crystals.

The crystalline product (7.0531 g; 37.9 mmol 1 eq) was then neutralized with potassium carbonate K₂CO₃ (2.6597 g; 19.3 mmol; 0.5 eq) in methanol (40 mL). The resulting solution was stirred for 2 hours and 30 minutes and filtrated. The filtrate was concentrated with a rotative evaporator and dried under vacuum in a dessicator for 12 h. A white solid (compound 17) (4.7214 g yield of 55.7% for this step and 35.7% for the entire procedure) was obtained.

### Synthesis of Compound 18

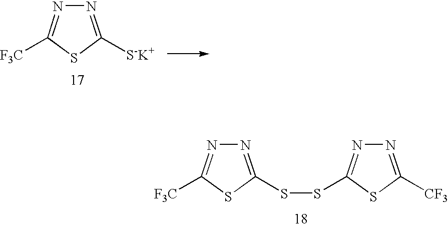

Compound 17 (200 mg; 0.89 mmol, 1 eq) was introduced in a 50 mL reaction flask filled with H₂O (20 mL) so as to obtain a solution. I₂ (50.3 mg; 0.44 mmole; 0.5 eq) was added to this solution. Immediately after the addition of iodine, a white solid in suspension was appeared. The solution was stirred until I₂ was dissolved and the white solid was filtrated under vacuum with a Büchner funnel fitted with a Whatman™ filter (no. 40: Ashless). The solid was rinsed with H₂O (100 mL) and dried under vacuum in a dessicator for 24 h to give 292.3 mg (yield of 90%) of product 18.

Some experiments have been made with the redox couple 3/5, which is as follows:

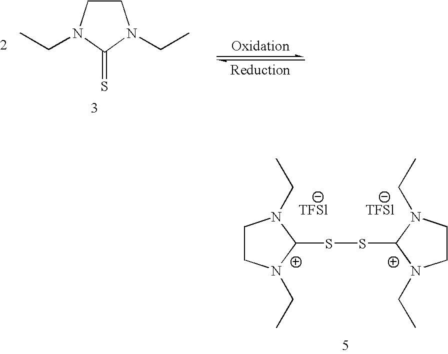

Various cyclic voltammetry experiments were carried out using the redox couple 3/5.

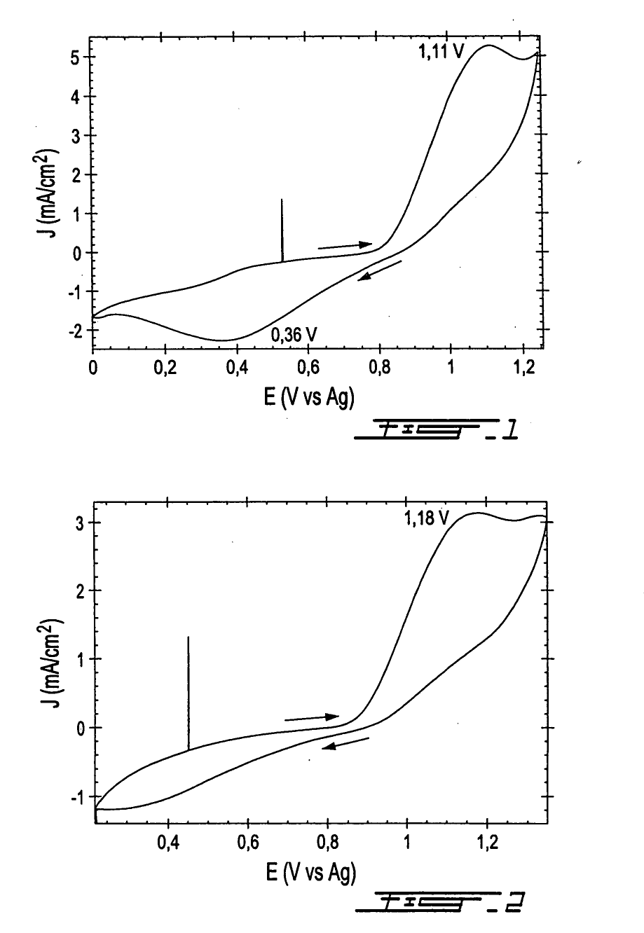

In FIG. 1, there is shown a cyclic voltammogram of a solution comprising compound 3 (1,3-diethyl-imidazolidine-2-thione) (0.25 M) and compound 5 (disulfide form)-(0.25 M) in EMITFSI at 22° C. A platinum electrode (A=0.0249 cm²) was used as working electrode and referenced to an Ag wire. Scan rate was 100 mV/s.

In FIG. 2, there is shown a cyclic voltammogram of a solution comprising compound 3 (1,3-diethyl-imidazolidine-2-thione) (0.25 M) and compound 5 (disulfide form) (0.13 M) in EMITFSI at 22° C. A platinum electrode (A=0.0249 cm²) was used as working electrode and referenced to an Ag wire. Scan rate was 100 mV/s.

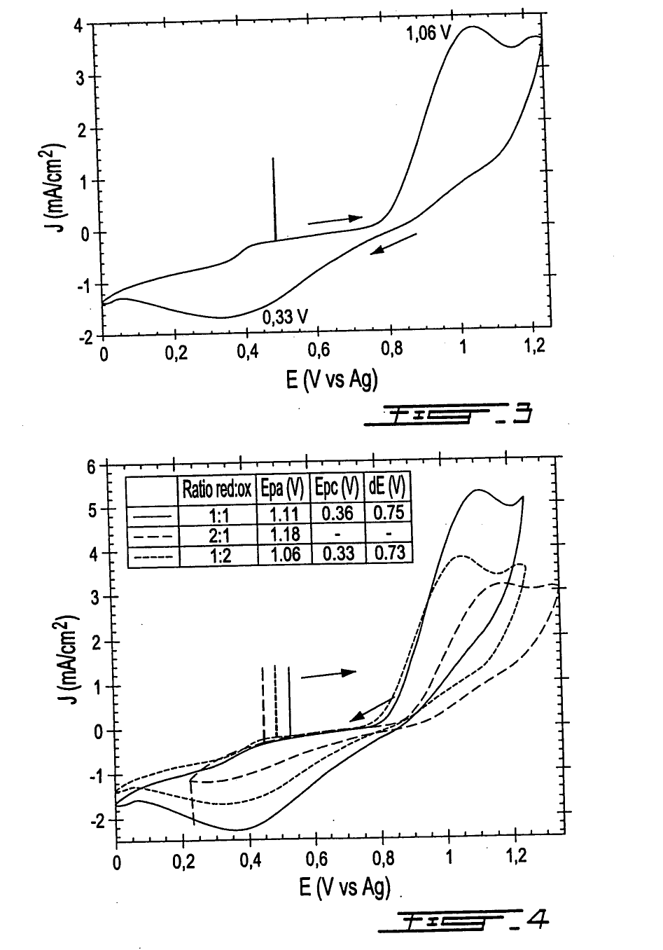

In FIG. 3, there is shown a cyclic voltammogram of a solution comprising compound 3 (1,3-diethyl-imidazolidine-2-thione) (0.13 M) and compound 5 (disulfide form) (0.25 M) in EMITFSI at 22° C. A platinum electrode (A=0.0249 cm²) was used as working electrode and referenced to an Ag wire. Scan rate was 100 mV/s.

In FIG. 4, there is shown cyclic voltammograms of three solutions comprising compounds 3 and 5 at different ratios (compound 3: compound 5) (1:1; 2:1; 1:2), in EMITFSI at 22° C. A platinum electrode (A=0.0249 cm²) was used as working electrode and referenced to an Ag wire. Scan rate was 100 mV/s.

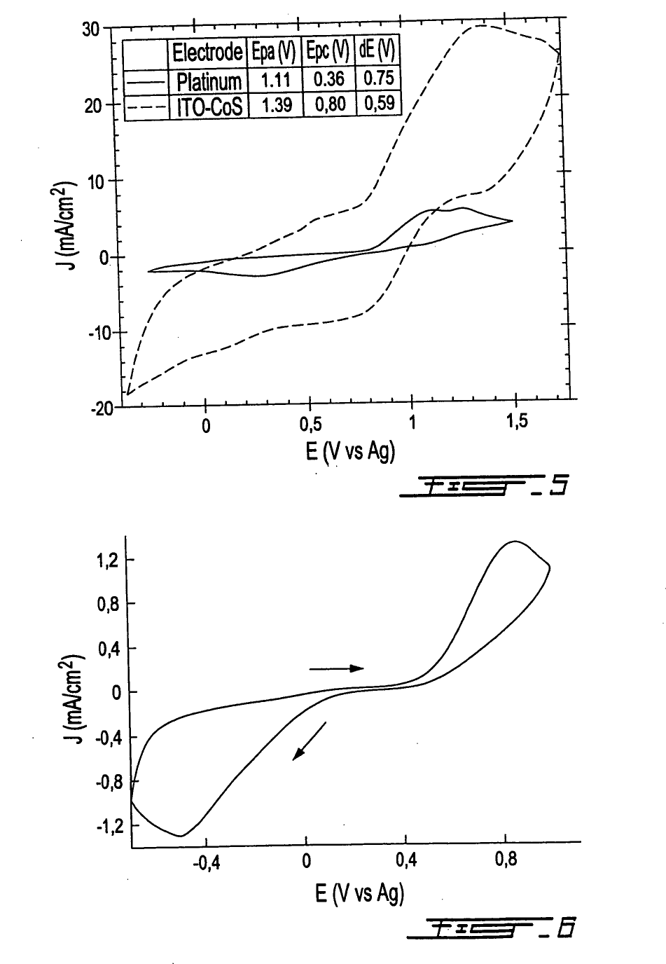

In FIG. 5, there is shown cyclic voltammograms of a solution comprising compound 3 (1,3-diethyl-imidazolidine-2-thione) (0.25 M) and compound 5 (disulfide form) (0.5 M) in EMITFSI at 22° C. A platinum electrode (A=0.0249 cm²) or an ITO-CoS electrode (surface area of 0.1 cm²) was used as working electrode and referenced to an Ag wire. Scan rate was 50 mV/s. The ITO-CoS electrode is described in US 20050089681, which is hereby incorporated by reference in its entirety.

The tests carried out show that 1,3-diethyl-imidazolidine-2-thione and its disulfide is a good redox couple which has the potential to replace the redox couple used in Grätzel solar cells (DSSCs using I⁻/I₃⁻). The good results obtained in conductivity (electrical properties) and in cyclic voltammetry (electrochemical properties) prove it. Moreover, it was observed that such a composition is substantially colorless or substantially optically clear. It should be noted that the Red:Ox ratio has more influence on the current density (J_{1:1}>J_{1:2}>J_{2:1}) than on ΔEₚ values. The greater current densities were obtained for the 1:1 ratio. It is interesting to point out that the ITO-CoS electrode (see FIG. 5) improves the electrochemical reversibility, shifts the potentials towards a more positive area, enhances both the anodic and cathodic current densities, and increases the reversibility (ΔEₚ is decreased). Therefore, this electrode would act as an excellent catalyst to reduce the oxidized species in a photovoltaic device using an n-type semiconductor as the (photo)anode.

Table 1 gives the conductivity (×10⁻³ S/cm) of three solutions of 1,3-diethyl-imidazolidine-2-thione and its disulfide form in EMITFSI in different ratios (1:1 [0.1 M:0.1 M]; 2:1 [0.2 M:0.1 M]; 1:2 [0.1 M:0.2 M]). Four temperatures were studied (20, 40, 60 and 80° C.). The results show that the conductivity is higher than or equal to 6.0×10⁻³ S/cm at 20° C., which represents an excellent value for a (photo)electrochemical device. As expected, conductivity values are enhanced when the temperature is increased, which could be attributed to the significant decrease of viscosity of EMITFSI at higher temperatures.

TABLE 1

Conductivity (×10⁻³ S/cm)

| | 20° C. | 40° C. | 60° C. | 80° C. |
|---|---|---|---|---|
| Ratio 1:1 | 6.29 | 11.61 | 18.96 | 27.17 |
| Ratio 2:1 | 6.76 | 12.58 | 20.33 | 29.15 |
| Ratio 1:2 | 6.00 | 11.14 | 18.29 | 26.43 |

Some experiments have also been made with the redox couple 7/8, which is as follows:

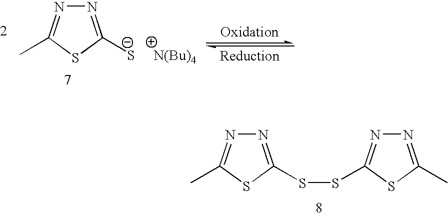

In FIG. 6, there is shown a cyclic voltammogram [I (mA. cm⁻²) vs E (vs Ag)] of a solution comprising compound 7 (tetrabutylammonium salt of 5-methyl-2-mercapto-1,3,4-thiadiazole) (75 mM) and compound 8 (25 mM) in EMITFSI at 22° C. A platinum electrode (surface area of 0.025 cm²) was used as working electrode and referenced to an Ag wire. The initial scan direction was oxidizing and the scan rate used was 50 mV. s⁻¹. The results demonstrate that the redox couple is less reversible than the one formed with compounds 3 and 5 (see FIG. 4), and that the anodic and cathodic current densities are lower. Corrosion tests were also carried out on the redox couple 7/8, and it was shown that over a period of 4 months, this redox couple did not corrode silver.

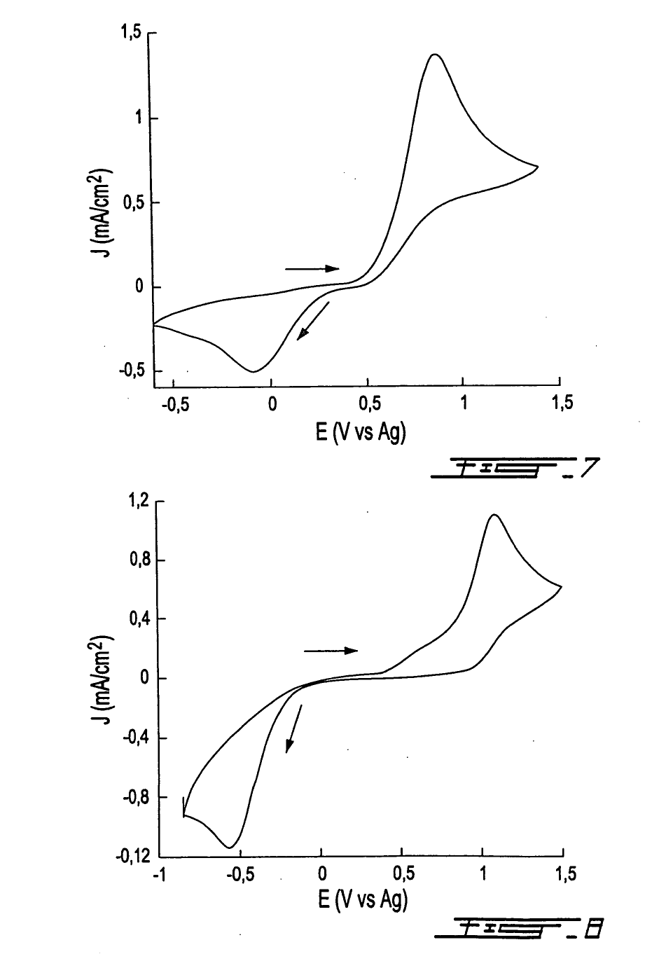

In FIG. 7, there is shown a cyclic voltammogram of a solution comprising compound 9 (0.75 M) and compound 10 (disulfide form) (0.25 M) in EMITFSI at 22° C. A platinum electrode (A=0.0249 cm²) was used as working electrode and referenced to an Ag wire. Scan rate was 50 mV/s. The results show that the redox couple 9/10 is more reversible than the redox couple 7/8 (see FIG. 6).

In FIG. 8, there is shown a cyclic voltammogram of a solution comprising compound 11 (0.66 M) and compound 12 (disulfide form) (0.34 M) in DMF-DMSO: 60-40 containing TBAP (0.2 M), at 22° C. A platinum electrode (A=0.0249 cm²) was used as working electrode and referenced to an Ag wire. Scan rate was 50 mV/s. The results show that the redox couple 11/12 is much less reversible than the redox couple 9/10 (see FIG. 7), probably due to the use of a less conducting electrolytic medium (an ionic liquid is not utilized as the solvent of the redox couple 11/12).

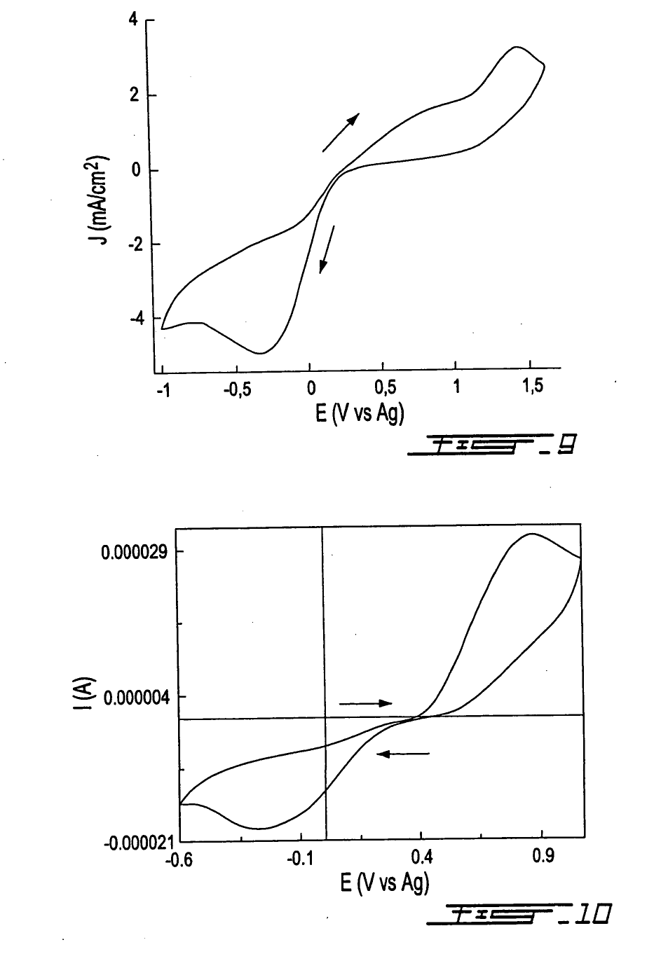

In FIG. 9, there is shown a cyclic voltammogram of a solution comprising compound 13 (0.25 M) and compound 14 (disulfide form) (0.75 M) in DMF-DMSO: 6040 containing TBAP (0.2 M), at 22° C. A platinum electrode (A=0.0249 cm²) was used as working electrode and referenced to an Ag wire. Scan rate was 50 mV/s. It can be noted interestingly that the redox couple 13/14 leads to enhanced current densities.

In FIG. 10, there is shown a cyclic voltammogram [I (A) vs E (V vs Ag)] of a solution comprising compound 17 (83.3 mM) and compound 18 (disulfide form) (16.3 mM) in EMITFSI at 22° C. A platinum electrode (A=0.0249 cm²) was used as working electrode and referenced to an Ag wire. Scan rate was 50 mV/s. The results demonstrate that the presence of the ionic liquid EMITFSI in the solution favors a better electrochemical reversibility, when compared to the redox couples 11/12 (see FIG. 8) and 13/14 (see FIG. 9).

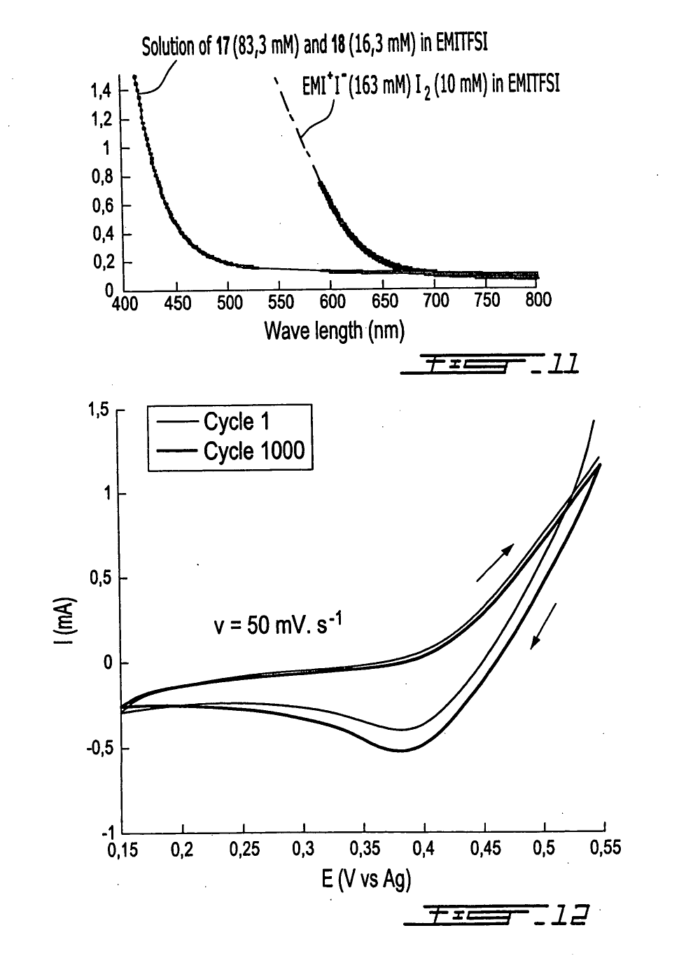

In FIG. 11, there is shown a comparison between the UV-visible spectrum of a solution comprising compounds 17 (83.3 mM) and 18 (16.3 mM) in EMITFSI and a UV-visible spectrum of EMI⁺I⁻ (163 mM)/I₂ (10 mM) in EMITFSI (redox couple used in Grätzel solar cells). As it can be seen from FIG. 11, the solution comprising compounds 17 and 18 in EMITFSI absorbs only partially in the visible area of the spectrum (more significantly at wavelengths lower than 500 nm), which contrasts with the solution of EMI⁺I⁻/I₂ in EMITFSI since the latter considerably absorbs in the visible area of the spectrum at wavelengths lower than 650 nm. FIG. 11 thus demonstrates that the composition comprising compounds 17 and 18 is substantially colorless or substantially optically clear.

In FIG. 12, there is shown a stability test that was performed on the solution comprising compounds 17 and 18 in EMITFSI (the solution tested in FIGS. 10 and 11) The test was carried out at a temperature of 70° C. and 1000 cycles were performed as shown on the cyclic voltammogram of FIG. 12. It can thus be said that the redox couple 17/18 has a high electrochemical and thermal stability. An ITO-CoS electrode (surface area of 0.25 cm²) was used as working electrode and referenced to an Ag wire.

While the invention has been described in connection with specific embodiments thereof, it will be understood that it is capable of further modifications and this application is intended to cover any variations, uses, or adaptations of the invention following, in general, the principles of the invention and including such departures from the present disclosure as come within known or customary practice within the art to which the invention pertains and as may be applied to the essential features herein before set forth, and as follows in the scope of the appended claims.

1. A composition comprising a first compound chosen from compounds of formulas (I) and (III) and a second compound chosen from compounds of formulas (II) and (IV): 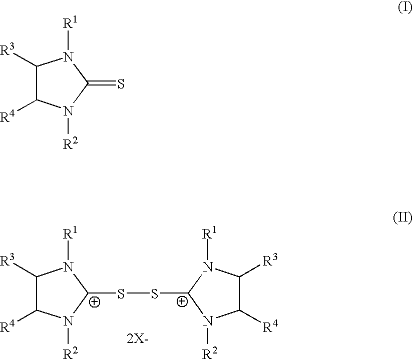
A-S⁻M⁺ (III)
A-S—S-A (IV)
wherein
R¹ and R² are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, or R¹ and/or R² is part of a polymer chain or network
R³ and R⁴ are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, F, Cl, Br, I, CF₃, CN, SO₃H, CₙF₂ₙ₊₁, HCₙF₂ₙ₊₁—, CF₃O, CₙF₂ₙ₊₁O—, HCₙF₂ₙ₊₁O—, CF₃S—, CₙF₂ₙ₊₁S—, HCₙF₂ₙ₊₁S—ClCₙF₂ₙ₊₁—, ClCₙF₂ₙ₊₁O—, ClCₙF₂ₙ₊₁S—, BrCₙF₂ₙ₊₁—, BrCₙF₂ₙ₊₁O—, BrCₙF₂ₙ₊₁S—, ICₙF₂ₙ₊₁—, ICₙF₂n+10, ICₙF₂ₙ₊₁S—, CH₂═CHCₙF₂ₙ₊₁—, CH₂═CHCₙF₂ₙ₊₁—, CH₂═CHCₙF₂ₙ₊₁S—, R²OCₙF₂ₙ₊₁—, R²OCₙF₂ₙ₊₁O—, R²OCₙF₂ₙ₊₁S—, CF₃CH₂—, CF₃CH₂O—, (CF₃)₂CH—, (CF₃)₂CHO—, CHF₂—, CHF₂O—, CHF₂S—, CClF₂—, CClF₂O—, CClF₂S—, CCl₂F—, CCl₂FO—, CClF₂S—, CCl₃—, CCl₃O, C₆F₅—, CF₃C₆F₄—, C₆F₅O—, CF₃C₆F₄O, 3,5-(CF₃)₂C₆H₂—, C₆Cl₅—, C₆Cl₅O—, FSO₂CF₂—, ClSO₂(CF₂)ₙ—, ⁻SO₃(CF₂)ₙ—, ⁻CO₂(CF₂)ₙ—, FSO₂N⁽⁻⁾SO₂(CF₂)ₙ—, CF₃SO₂N⁽⁻⁾SO₂(CF₂)ₙ—, CₙF₂ₙ₊₁ SO₂N⁽⁻⁾SO₂(CF₂)ₙ—, R²SO₂N⁽⁻⁾SO₂(CF₂)ₙ—, FSO₂(CF₂)ₙ—, ClSO₂(CF₂)ₙ—, CₙF₂ₙ₊₁SO₂N⁽⁻⁾(CF₂)ₙ—, and R²SO₂N⁽⁻⁾(CF₂)ₙ— or
R³ and/or R⁴ is part of a polymer chain or network, or absent
X⁻ is (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻NO₃⁻, 2.3HF, Cl⁻, Br⁻, I⁻, PF₆⁻, BF₄⁻, ClO₄, SCN⁻;
M is H, an inorganic cation, or an organic cation;
A is a C₁-C₁₂ heteroaryl, a C₁-C₁₂ heterocyclyl, C₆-C₁₂ aryl, C₆-C₃₀ aralkyl, or C₆-C₃₀ alkylaryl
wherein the alkyl, cycloalkyl, heterocyclyl, alkenyl, alkynyl, aryl, aralkyl, alkylaryl, heteroaryl, alkylheteroaryl, and alkylheterocyclyl optionally includes a heteroatom in the form of —O—, ═N—, —S—, ═P—, ═(P═O), —SO—, —SO₂—;
wherein said alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from R³, R⁴, F, Cl, Br, I, OH, a C₁-C₆ alkoxy, a C₁-C₆ hydroxy alkyl, NO₂, CN, CF₃, SO₃—, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂f—, CH₂═CHCₚH₂ₚ—, CH₂═CHC₆H₅—, CH₂═CHC₆H₄CₚH₂ₚ₊₁—, and CH₂═CHCₚH₂ₚC₆H₄—;
n is an integer having a value from 1 to 48;
m is an integer having a value from 2 to 12; and
p is an integer having a value from 1 to 48.

2. (canceled)

3. The composition of claim 1, wherein said composition comprises a compound of formula (III) and a compound of formula (IV), and wherein A is of formula: 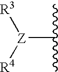
wherein Z is chosen from 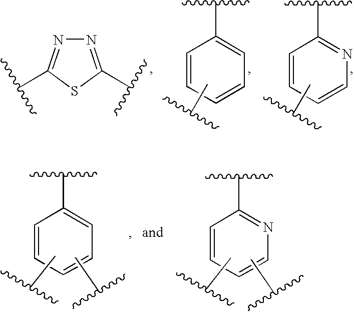
wherein R₃ and R₄ are as previously defined.

4. The composition of claim 1, wherein said composition comprises a compound of formula (III) and a compound of formula (IV), and wherein A is chosen from thiadiazoles, pyridines, and phenylenes,
said thiadiazoles, pyridines, and phenylenes being unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂ₙ—, CH₂═CHCₚH₂ₚ—, CH₂═CHC₆H₅—, CH₂═CHC₆H₄CₚH₂ₚ₊₁—, and CH₂═CHCₚH₂ₚC₆H₄—;

5. The composition of claim 1, wherein said composition comprises a compound of formula (III) and a compound of formula (IV), and wherein A is chosen from

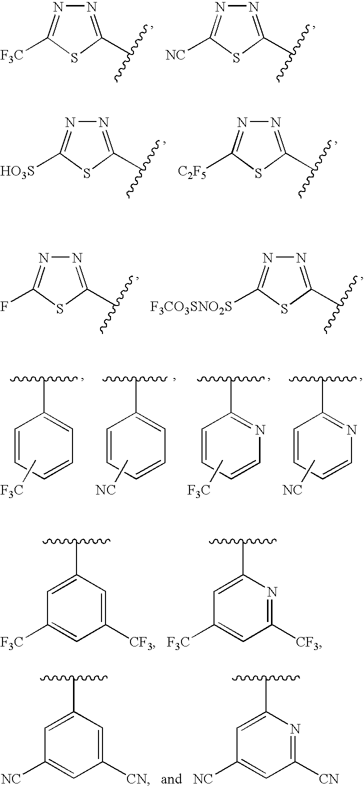

6. (canceled)

7. (canceled)

8. The composition of claim 1, wherein said composition comprises a compound of formula (I) and a compound of formula (II) or a compound of formula (III) and a compound of formula (IV).

9. The composition of claim 1, wherein said composition comprises a compound of formula (I) and a compound of formula (II), and wherein X⁻ is (CF₃SO₂)₂N⁻, (C₂F₅SO₂)₂N⁻, (CF₃SO₂)₃C⁻, CF₃SO₃⁻, (CN)₂N⁻, PF₆⁻, BF₄⁻ or ClO₄⁻.

10. The composition of claim 9, wherein X⁻ is (CF₃SO₂)₂N⁻.

11. The composition of any one of claims 3 to 5, wherein M is an organic cation chosen from a positively charged C₁-C₁₂ heteroaryl or a C₁-C₁₂ heterocyclyl, wherein said heteroaryl or said heterocyclyl is unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂n—, CH₂═CHCₚH₂ₚ—, CH₂═CHC₆H₅—, CH₂═CHC₆H₄CₚH₂ₚ₊₁—, and CH₂═CHCₚH₂ₚC₆H₄—.

12. The composition of any one of claims 3 to 5, wherein M is an organic cation is of formula 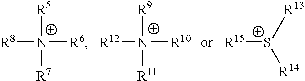
wherein
R⁵, R⁶, R⁷ and R⁸ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl;
R⁹, R¹⁰, R¹¹ and R¹² are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl; and
R¹³, R¹⁴ and R¹⁵ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl,
wherein said alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, C₆H₅CₚH₂ₚ—, CₚH₂ₚ₊₁C₆H₄—, CₚH₂ₚ₊₁C₆H₄CₙH₂n—, CH₂═CHCₚH₂ₚ—, CH₂═CHC₆H₅—, CH₂═CHC₆H₄CₚH₂ₚ₊₁—, and CH₂═CHCₚH₂ₚC₆H₄—.

13. The composition of any one of claims 3 to 5, wherein M is an organic cation chosen from N-substituted imidazoliums, said substituent being a C₁-C₁₂ alkyl which is linear or branched.

14. The composition of any one of claims 3 to 5, wherein said cation is an organic cation chosen from tetralkylammoniums, wherein each of said alkyl groups is independently C₁-C₁₂ alkyl which is linear or branched.

15. The composition of any one of claims 1, 3 to 5 and 8 to 10, wherein said composition further comprises a solvent chosen from nitriles (such as CH₃CN), CH₂Cl₂, alcohols (such as ethanol, isopropanol), DMSO, amides (such as DMF), hexane, heptane, toluene, linear carbonates (such as dimethylcarbonate, diethylcarbonate, ethylmethylcarbonate), cyclic esters (such as ethylene carbonate, propylene carbonate), urea (tetramethylurea), ionic liquids such as dialkylimidazolium, trialkylsulfonium, and quaternary amine (such as C₁-C₂₀ tetraalkylammonium) and quaternary phosphonium (such as C₁-C₂₀ tetraalkylphosphonium or C₆-C₁₂ tetraarylphosphonium) salts associated with stable anion such as (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻, NO₃⁻, 2.3HF, Cl⁻, Br⁻, I⁻, PF₆⁻, BF₄⁻, ClO₄⁻, SCN⁻, and mixtures thereof.

16. The composition of claim 15, wherein said solvent is nitriles (such as CH₃CN), amides (such as DMF), linear carbonates (such as dimethylcarbonate, diethylcarbonate, ethylmethylcarbonate), cyclic esters (such as ethylene carbonate, propylene carbonate), ionic liquids such as dialkylimidazolium, trialkylsulfonium, and quaternary amine (such as C₁-C₂₀ tetraalkylammonium) and quaternary phosphonium (such as C₁-C₂₀ tetraalkylphosphonium or C₆-C₁₂ tetraarylphosphonium) salts associated with stable anion such as (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻, NO₃⁻, 2.3HF, Cl⁻, Br⁻, I⁻, PF₆⁻, BF₄⁻, ClO₄⁻, SCN⁻ and mixtures thereof.

17. The composition of any one of claims 1, 3 to 5 and 8 to 10, wherein said first compound is present in said composition in a molar ratio of about 0.1 to about 99.9% and said second compound is present in a molar ratio about 99.9 to about 0.1%.

18. The composition of any one of claims 1, 3 to 5 and 8 to 10, wherein said first compound is present in said composition in a molar ratio of about 5.0 to about 95.0% and said second compound is present in a molar ratio about 95.0 to about 5.0%.

19. The composition of any one of claims 1, 3 to 5 and 8 to 10, wherein said composition is in the form of an uncolored and/or translucid solution, or in the form of a substantially optically clear solution.

20. The composition of claim 1, wherein said first compound and said second compound are respectively:

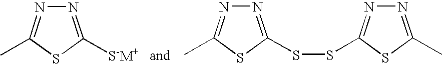

21. The composition of claim 1, wherein said first compound and said second compound are respectively:

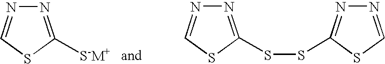

22. The composition of claim 1, wherein said first compound and said second compound are respectively:

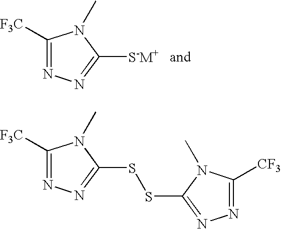

23. The composition of claim 1, wherein said first compound and said second compound are respectively:

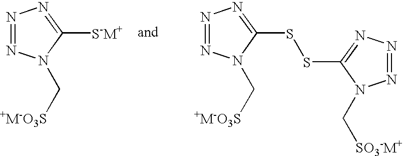

24. The composition of claim 1, wherein said first compound and said second compound are respectively:

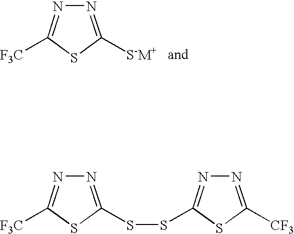

25. The composition of any one claims 20 to 24, wherein M⁺ is an organic cation chosen from tetralkylammoniums, wherein each of said alkyl groups is independently a C₁-C₁₂ alkyl which is linear or branched, and N-substituted imidazoliums, wherein said substituents are each independently chosen from C₁-C₆ alkyl groups which are linear or branched.

26. The composition of any of claims 1, 9, and 10, wherein said first compound and said second compound are respectively:

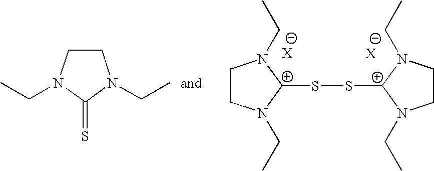

27. The composition of claim 26, wherein X⁻ is (CF₃SO₂)₂N⁻.

28. The composition of any one of claims 1, 3 to 5 and 20 to 24, wherein M⁺ is chosen from Li⁺, Na⁺ and K⁺, and Cs⁺.

29. (canceled)

30. A redox couple according to scheme 1 or scheme 2: 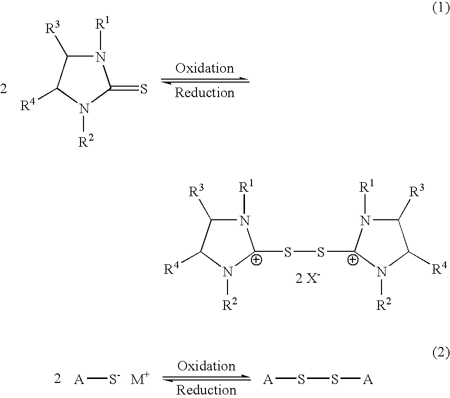
wherein
R¹ and R² are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, or R¹ and/or R² is part of a polymer chain or network
R³ and R⁴ are the same or different and are chosen from a hydrogen atom, C₁-C₃₀ alkyl which is linear or branched and optionally halogenated, C₃-C₁₂ cycloalkyl, C₁-C₁₂ heterocyclyl, C₂-C₈ alkenyl, C₂-C₈ alkynyl, C₆-C₁₂ aryl, C₆-C₃₀ aralkyl, C₆-C₃₀ alkylaryl, and C₁-C₁₂ heteroaryl, C₆-C₃₀ alkylheteroaryl, and C₆-C₃₀ alkylheterocyclyl, F, Cl, Br, I, CF₃, CN, SO₃H, CₙF₂ₙ₊₁, HCₙF₂ₙ₊₁—, CF₃O—, CₙF₂ₙ₊₁O—, HCₙF₂ₙ₊₁O—, CF₃S—, CₙF₂₊₁S—, HCₙF₂ₙ₊₁S—, ClCₙF₂ₙ₊₁—, ClCₙF₂ₙ₊₁O—, ClCₙF₂ₙ₊₁S—, BrCₙF₂ₙ₊₁—, BrCₙF₂ₙ₊₁O—, BrCₙF₂ₙ₊₁S—, ICₙF₂ₙ₊₁—, ICₙF₂ₙ₊₁O—, ICₙF₂ₙ₊₁S—, CH₂═CHCₙF₂ₙ₊₁—, CH₂═CHCₙF₂ₙ₊₁O—, CH₂═CHCₙF₂ₙ₊₁S—, R²OCₙF₂ₙ₊₁—, R²OCₙF₂ₙ₊₁O—, R²OCₙF₂ₙ₊₁S—, CF₃CH₂—, CF₃CH₂O—, (CF₃)₂CH—, (CF₃)₂CHO—, CHF₂—, CHF₂O—, CHF₂S—, CClF₂—, CClF₂O—, CClF₂S—, CCl₂F—, CCl₂FO—, CClF₂S—, CCl₃—, CCl₃O—, C₆F₅—, CF₃C₆F₄—, C₆F₅s—, CF₃C₆F₄O—, 3,5-(CF₃)₂C₆H₂—, C₆Cl₅—, C₆Cl₅O—, FSO₂CF₂—, ClSO₂(CF₂)ₙ—, SO₃(CF₂)ₙ—, CO₂(CF₂)ₙ—, FSO₂N⁽⁻⁾SO₂(CF₂)ₙ—, CF₃SO₂N⁽⁻⁾SO₂(CF₂)ₙ—, CₙF₂ₙ₊₁SO₂N⁽⁻⁾SO₂(CF₂)ₙ—, R²SO₂N⁽⁻⁾SO₂(CF₂)ₙ—, FSO₂(CF₂)ₙ—, ClSO₂(CF₂)ₙ—, —SO₃(CF₂)ₙ—, CₙF₂ₙ₊₁SO₂N⁽⁻⁾(CF₂)ₙ—, and R²SO₂N⁽⁻⁾(CF₂)ₙ—
or R³ and/or R⁴ is part of a polymer chain or network, or absent
X⁻ is (FSO₂)₂N⁻, (CF₃SO₂)₂N⁻, (C₂F₅SO₂)₂N⁻, (CF₃SO₂)₃C⁻, CF₃SO₃⁻, CF₃COO⁻, AsF₆⁻, CH₃COO⁻, (CN)₂N⁻, (CN)₃C⁻NO₃⁻, 2.3HF, Cl⁻, Br⁻, I⁻, PF₆⁻, BF₄⁻, ClO₄, SCN⁻;
M is H, an inorganic cation, or an organic cation;
A is a C₁-C₁₂ heteroaryl, a C₁-C₁₂ heterocyclyl, C₆-C₁₂ aryl, C₆-C₃₀ aralkyl, or C₆-C₃₀ alkylaryl
wherein said alkyl, cycloalkyl, heterocyclyl, alkenyl, alkynyl, aryl, aralkyl, alkylaryl, heteroaryl, alkylheteroaryl, and alkylheterocyclyl optionally includes a heteroatom in the form of —O—, ═N—, —S—, ═P—, ═(P═O), —SO—, —SO₂—;
wherein said alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from R³, R⁴, F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂f—, CH₂═CHCₚH₂ₚ—, CH₂═CHC₆H₅—, CH₂═CHC₆H₄CₚH₂ₚ₊₁—, and CH₂═CHCₚH₂ₚC₆H₄—;
n is an integer having a value from 1 to 48;
m is an integer having a value from 2 to 12; and
p is an integer having a value from 1 to 48.

31. The redox couple of claim 30, wherein said redox couple is a redox couple as defined in Scheme (2) and wherein A is of formula 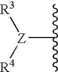
wherein Z is chosen from 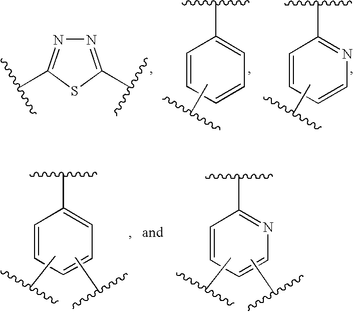
wherein R₃ and R₄ are as previously defined.

32. The redox couple of claim 30, wherein said redox couple is a redox couple as defined in Scheme (2) and wherein A chosen of thiadiazoles, pyridines, and phenylenes,
said thiadiazoles, pyridines, and phenylenes being unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, Ph₂P(O)—, Ph₂P—, Me₂P(O)—, Me₂P, Ph₂P(S), Me₂P(S), Ph₃P═N—, Me₃P═N—, C₆H₅CₚH₂ₚ—, CₚH₂ₚ₊₁C₆H₄—, CₚH₂ₚ₊₁C₆H₄CₙH₂n—, CH₂═CHCₚH₂ₚ—, CH₂═CHC₆H₅—, CH₂═CHC₆H₄CₚH₂ₚ₊₁—, and CH₂═CHCₚH₂ₚC₆H₄—;

33. The redox couple of claim 30, wherein said redox couple is a redox couple as defined in Scheme (2) and wherein A is chosen from

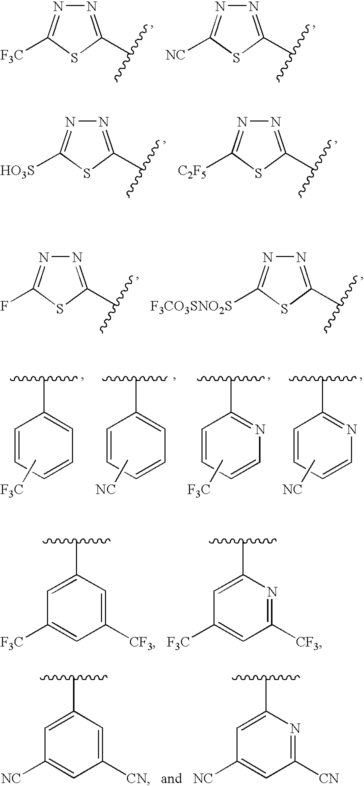

34. The redox couple of claim 30, wherein said redox couple is a redox couple as defined in Scheme (1) and wherein X⁻ is (CF₃SO₂)₂N⁻, (FSO₂)₂N⁻, (CF₃SO₂)₃C⁻, CF₃SO₃⁻, (CN)₂N⁻, PF₆⁻, BF₄⁻ or ClO₄⁻.

35. The redox couple of claim 34, wherein X⁻ is (CF₃SO₂)₂N⁻.

36. The redox couple of any one of claims 30 to 33, wherein M is an organic cation chosen from a positively charged C₁-C₁₂ heteroaryl or a C₁-C₁₂ heterocyclyl, wherein said heteroaryl or said heterocyclyl is unsubstituted or substituted with a C₁-C₁₂ alkyl which is linear or branched.

37. The redox couple of any one of claims 30 to 33, wherein M is an organic cation chosen from N-substituted imidazoliums, wherein said substituents are C₁-C₁₂ alkyls which are linear or branched.

38. The redox couple of any one of claims 30 to 33, wherein M is an organic cation of formula 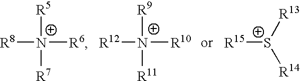
wherein
R⁵, R⁶, R⁷ and R⁸ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl;
R⁹, R¹⁰, R¹ and R¹² are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl; and
R¹³, R¹⁴ and R¹⁵ are same or different and each independently represent a C₁-C₂₀ alkyl which is linear or branched, C₃-C₁₂ cycloalkyl, C₁-C₁₂ heterocyclyl, C₂-C₂₀ alkenyl, C₂-C₂₀ alkynyl, C₆-C₁₂ aryl, C₆-C₂₀ aralkyl, C₆-C₂₀ alkylaryl, and C₁-C₁₂ heteroaryl,
wherein said alkyl, cycloalkyl, heterocyclyl, alkenyl, alkynyl, aryl, aralkyl, alkylaryl, heteroaryl, alkylheteroaryl, and alkylheterocyclyl being unsubstituted or substituted with 1 to 3 substituents chosen from F, Cl, Br, I, OH, a C₁-C₆ alkoxy, a C₁-C₆ hydroxy alkyl, NO₂, CN, CF₃, SO₃⁻, CₙF₂ₙ₊₁, C₁-C₁₂ alkyl which is linear or branched, C₆-C₁₂ aryl, CₙH₂ₙ₊₁, C₆H₅CₚH₂ₚ—, CₚH₂ₚ₊₁C₆H₄—, CₚH₂ₚ₊₁C₆H₄CₙH₂n—, CH₂═CHCₚH₂ₚ—, CH₂═CHC₆H₅—, CH₂═CHC₆H₄CₚH₂ₚ₊₁—, and CH₂═CHCₚH₂ₚC₆H₄—.

39. The redox couple of any one of claims 30 to 33, wherein said organic cation is chosen from tetralkylammoniums, wherein each of said alkyl groups is independently C₁-C₁₂ alkyl which is linear or branched.

40. The redox couple of claim 30, wherein said redox couple is as follows:

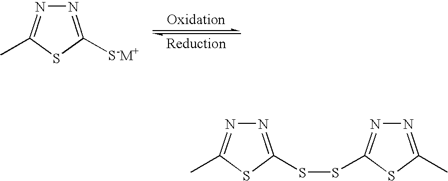

41. The redox couple of claim 30, wherein said redox couple is as follows:

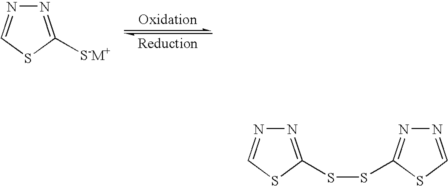

42. The redox couple of claim 30, wherein said redox couple is as follows:

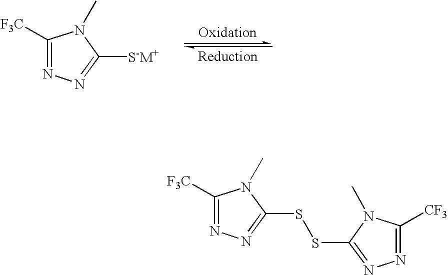

43. The redox couple of claim 30, wherein said redox couple is as follows:

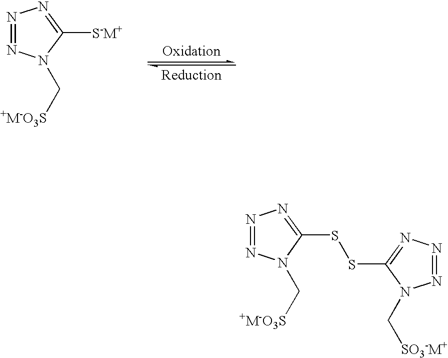

44. The redox couple of claim 30, wherein said redox couple is as follows:

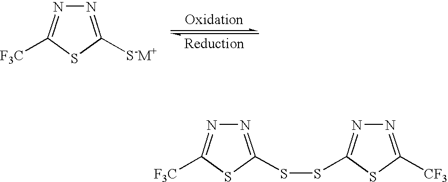

45. The redox couple of any one claims 40 to 44, wherein M⁺ is an organic cation chosen from tetralkylammoniums, wherein each of said alkyl groups is independently a C₁-C₁₂ alkyl which is linear or branched, and N-substituted imidazoliums, wherein said substituents are independently chosen from C₁-C₆ alkyl groups which are linear or branched.

46. The redox couple of claim 30, wherein said redox couple is as follows:

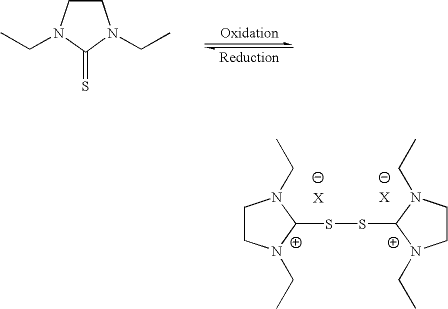

47. The redox couple of claim 46, wherein X⁻ is (CF₃SO₂)₂N⁻.

48. The redox couple of any one of claims 30 to 35 and 40 to 44, wherein M⁺ is chosen from Li⁺, Na⁺, K⁺, and Cs⁺.

49. A photovoltaic cell comprising an anode, a cathode, and a composition as defined in any one of claims 1, 3 to 5, 8 to 10 and 20 to 24.

50. A photovoltaic cell as defined in claim 49, further comprising at least one of a solvent, a polymer, a molten salt, an ionic liquid, a gel or any combination thereof.

51. A solar cell, a fuel cell, a battery, a sensor or a display comprising a composition as defined in any one of claims 1, 3 to 5, 8 to 10 and 20 to 24.

52. A photovoltaic cell comprising an anode, a cathode, and a redox couple as defined in any one of claims 30 to 35, 40 to 44, 46 or 47.

53. A photovoltaic cell as defined in claim 52, further comprising at least one of a solvent, a polymer, a molten salt, an ionic liquid, a gel or any combination thereof.

54. A solar cell, a fuel cell, a battery, a sensor or a display comprising a composition as defined in any one of claims 1, 3 to 5, 8 to 10 and 20 to 24.
